(19) United States
(12) Patent Application Publication
(10) Pub. No.: US 2015/0311122 A1
(43) Pub. Date: Oct. 29, 2015

(54) FORMING GATE TIE BETWEEN ABUTTING CELLS AND RESULTING DEVICE

(71) Applicant: Globalfoundries Inc., Grand Cayman (KY)

(72) Inventors: Mahbub RASHED, Cupertino, CA (US); Yunfei DENG, Fremont, CA (US); Juhan KIM, Santa Clara, CA (US); Jongwook KYE, Pleasanton, CA (US); Suresh VENKATESAN, Los Gatos, CA (US); Subramani KENGERI, San Jose, CA (US)

(73) Assignee: Globalfoundries Inc., Grand Cayman (KY)

(21) Appl. No.: 14/263,399

(22) Filed: Apr. 28, 2014

(51) Int. Cl. H01L 21/8234; H01L 27/088; H01L 29/66

(52) U.S. Cl. CPC H01L 21/823431; H01L 21/823437; H01L 21/823475; H01L 29/66545; H01L 27/0886

(57) ABSTRACT

Methods for forming abutting FinFET cells with a single dummy gate and continuous fins, and the resulting devices, are disclosed. Embodiments may include forming one or more continuous fins on a substrate, forming gates perpendicular to and over the one or more continuous fins to form a first FinFET cell and a second FinFET cell, and forming source and drain contact lines parallel to and between the gates, wherein a source contact line of the first FinFET cell is adjacent to a drain contact line of the second FinFET cell, and the source contact line and the drain contact line are on opposite sides of a gate.

### TECHNICAL FIELD

The present disclosure relates to FinFETs semiconductor devices. The present disclosure is particularly applicable to forming abutting FinFET cells for 14 nanometer (nm) technology nodes and beyond.

### BACKGROUND

In FinFET devices, two abutting cells require Fin-tucks, or covered ends of non-continuous fins at cell boundaries using two dummy gates. A Fin-tuck is necessary because of FinFET process complexity and manufacturability issues. However, the Fin-tuck results in a 10% area penalty. Such an area penalty also results in a 4% performance penalty and a 15% performance/power/area (PPA) penalty.

A need, therefore, exists for forming adjacent FinFET cells formed of continuous fins and with only one dummy gate separating the FinFET cells, and the resulting devices.

### SUMMARY

An aspect of the present disclosure is a method of forming abutting FinFET cells separated by a single dummy gate and having continuous fins.

Another aspect of the present disclosure is a device including abutting FinFET cells separated by a single dummy gate and having continuous fins.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming one or more continuous fins on a substrate; forming gates perpendicular to and over the one or more continuous fins to form a first FinFET cell and a second FinFET cell; and forming source and drain contact lines parallel to and between the gates, wherein a source contact line of the first FinFET cell is adjacent to a drain contact line of the second FinFET cell, and the source contact line and the drain contact line are on opposite sides of a gate.

An aspect of the present disclosure includes forming a gate tie extending a section of the source contact line to the gate. Another aspect includes forming a jog in the drain contact line at a section of the drain contact line adjacent to the gate tie. Yet another aspect includes, in forming the jog, forming a notch in a side of the drain contact line nearest to the gate tie. An additional aspect includes forming the notch using a cut mask on the drain contact line. A further aspect includes, in further forming the jog, forming a projection on a side of the drain contact line farthest from the gate tie. Yet another aspect includes the gate being a dummy gate.

Another aspect of the present disclosure is a device including: a substrate; one or more continuous fins on the substrate; gates perpendicular to and over the one or more continuous fins, forming a first FinFET cell and a second FinFET cell; and source and drain contact lines parallel to and between the gates, wherein a source contact line of the first FinFET cell is adjacent to a drain contact line of the second FinFET cell, and the source contact line and the drain contact line are on opposite sides of a gate.

An aspect includes a gate tie extending a section of the source contact line to the gate. A further aspect includes a jog in the drain contact line at a section of the drain contact line adjacent to the gate tie. Another aspect includes the jog including a notch in a side of the drain contact line nearest to the gate tie. Still another aspect includes the notch being formed using a cut mask on the drain contact line. Another aspect includes the jog further including a projection on a side of the drain contact line farthest from the gate tie. Yet an additional aspect includes the gate being a dummy gate.

According to the present disclosure, additional and/or alternative technical effects may be achieved in part by a method including: forming one or more continuous fins on a substrate; forming gates perpendicular to and over the one or more continuous fins to form a first FinFET cell and a second FinFET cell; and forming source and drain contact lines parallel to and between the gates, wherein a source contact line of the first FinFET cell is adjacent to a source contact line of the second FinFET cell on opposite sides of a gate.

A further aspect includes forming a short connecting the source contact line of the first FinFET cell to the source contact line of the second FinFET cell. Another aspect includes forming the short connected to the gate, wherein the gate is a dummy gate.

Another aspect of the present disclosure is a device including: a substrate; one or more continuous fins on the substrate; gates perpendicular to and over the one or more continuous fins, forming a first FinFET cell and a second FinFET cell; and source and drain contact lines parallel to and between the gates, wherein a source contact line of the first FinFET cell is adjacent to a source contact line of the second FinFET cell on opposite sides of a gate.

Further aspects include a short connecting the source contact line of the first FinFET cell to the source contact line of the second FinFET cell. Another aspect includes the short being connected to the gate, and the gate being a dummy gate.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 4 schematically illustrate a method for forming abutting FinFET cells with a source-to-source abutment, in accordance with an exemplary embodiment; and

FIGS. 5 through 10 schematically illustrate a method for forming abutting FinFET cells with a source-to-drain (or drain-to-source) abutment, in accordance with an alternative exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of the need for a Fin-tuck attendant upon abutting cells with non-continuous fins in FinFET devices. In accordance with embodiments of the present disclosure, continuous fins are used between abutting FinFET cells, reducing the space between the abutting cells to a single dummy gate with the addition of a connection mechanism that ties off the dummy gate to avoid design rule violations and shorts with other connections.

Methodology in accordance with an embodiment of the present disclosure includes forming one or more continuous fins on a substrate. The methodology further includes gates being formed perpendicular to and over the one or more continuous fins to form a first FinFET cell and a second FinFET cell. Source and drain contact lines are then formed parallel to and between the gates, with a source contact line of the first FinFET cell being adjacent to a drain contact line of the second FinFET cell, and the source contact line and the drain contact line being on opposite sides of a gate.

Methodology in accordance with another embodiment of the present disclosure includes forming one or more continuous fins on a substrate. The methodology further includes forming gates perpendicular to and over the one or more continuous fins to form a first FinFET cell and a second FinFET cell. Further, source and drain contact lines parallel to and between the gates are formed, with a source contact line of the first FinFET cell being adjacent to a source contact line of the second FinFET cell on opposite sides of a gate.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

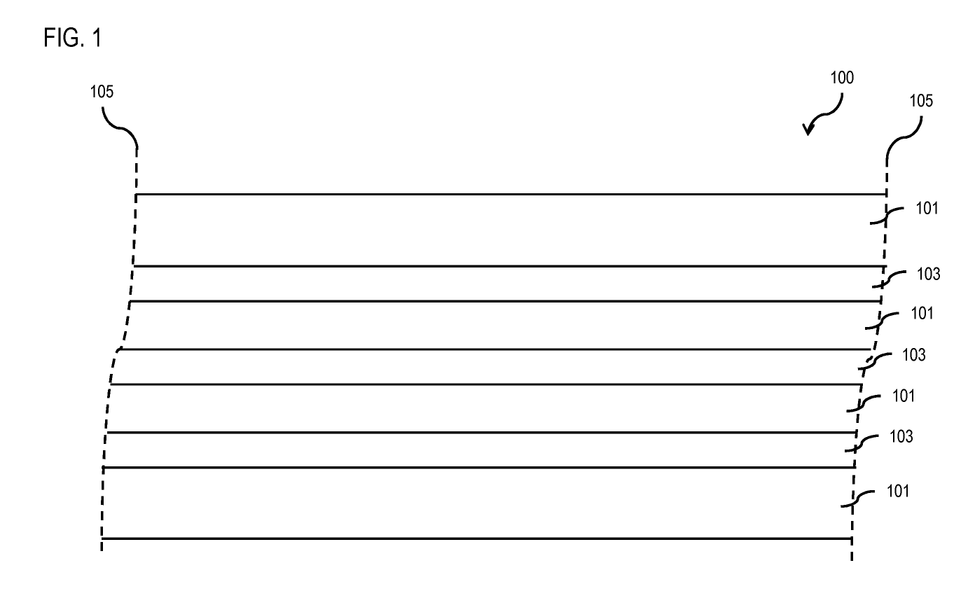

In view of the foregoing, when two FinFET cells abut, there are three situations that can occur: (1) source-to-source abutment, (2) drain-to-drain abutment, and (3) source-to-drain (or drain-to-source) abutment. Adverting to FIG. 1, a method for forming abutting cells sharing a common dummy gate for (1) source-to-source abutment, according to an exemplary embodiment, begins with a structure 100 including an active region 101 and fins 103. The active region 101 and fins 103 may be formed according to any conventional process. Although only three fins 103 are shown, there may be any number of fins. Further, the dashed lines 105 indicate that the active region 101 and fins 103 may extend beyond what is illustrated.

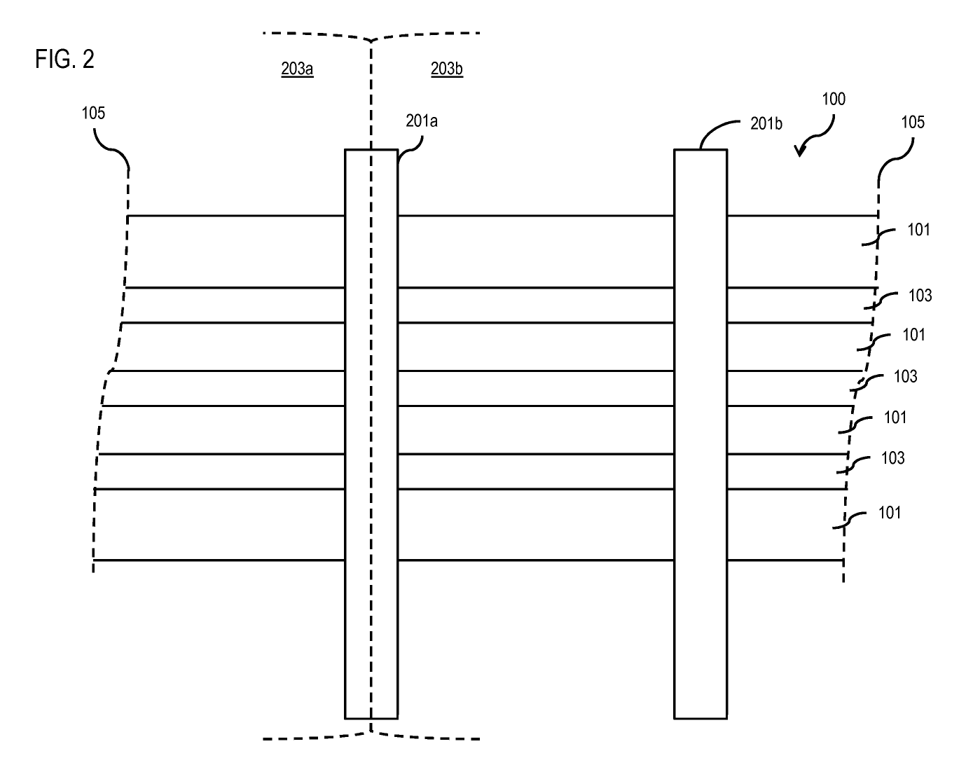

Gates 201a and 201b are then formed perpendicular to and over the fins 103, as illustrated in FIG. 2. The gates 201a and 201b may be formed according to any conventional process. Although only two gates 201a and 201b are shown, more than two gates may be formed when forming gates 201a and 201b (not shown for illustrative convenience). In the illustrated embodiment, gate 201a represents a dummy gate and separates cell 203a, left of gate 201a, from cell 203b, right of gate 201a. Because of the continuous active region 101 and fins 103, the cells 203a and 203b share the same active region 101 and fins 103. Further, according to the process discussed below, the cells 203a and 203b also share the same dummy gate, gate 201a.

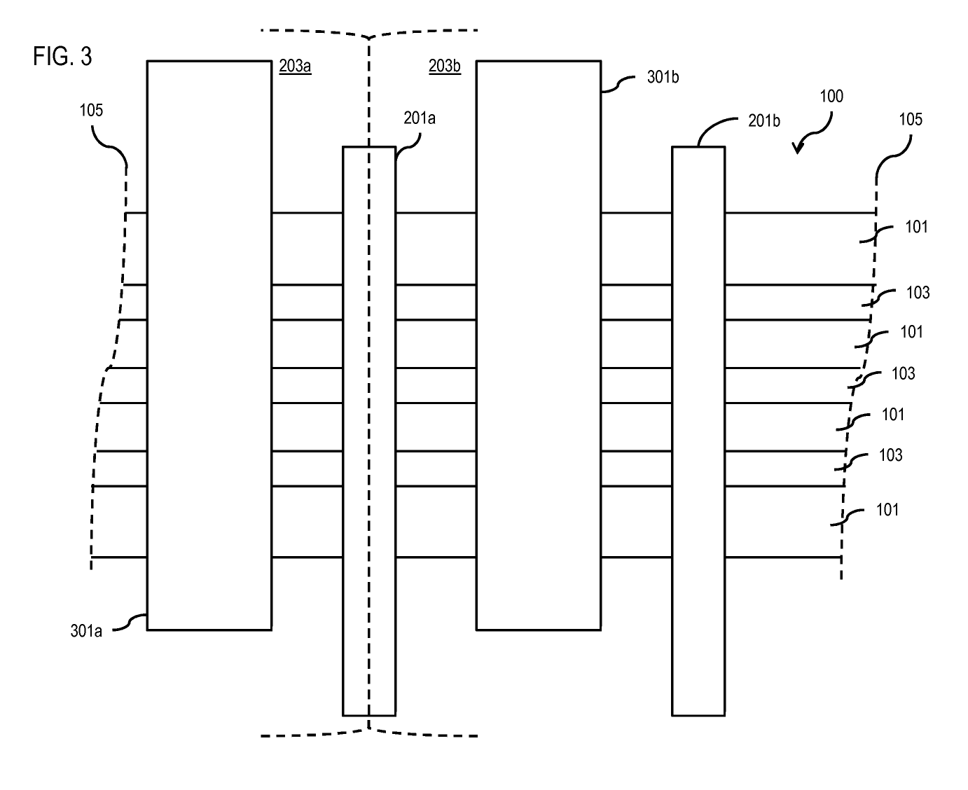

Adverting to FIG. 3, source contact lines 301a and 301b are then formed perpendicular to and over fins 103 on either side of gate 201a. The source contact lines 301a and 301b may be formed according to any conventional process. Although only two source contact lines 301a and 301b are illustrated, more than two source contact lines may be formed when forming source contact lines 301a and 301b (not shown for illustrative convenience).

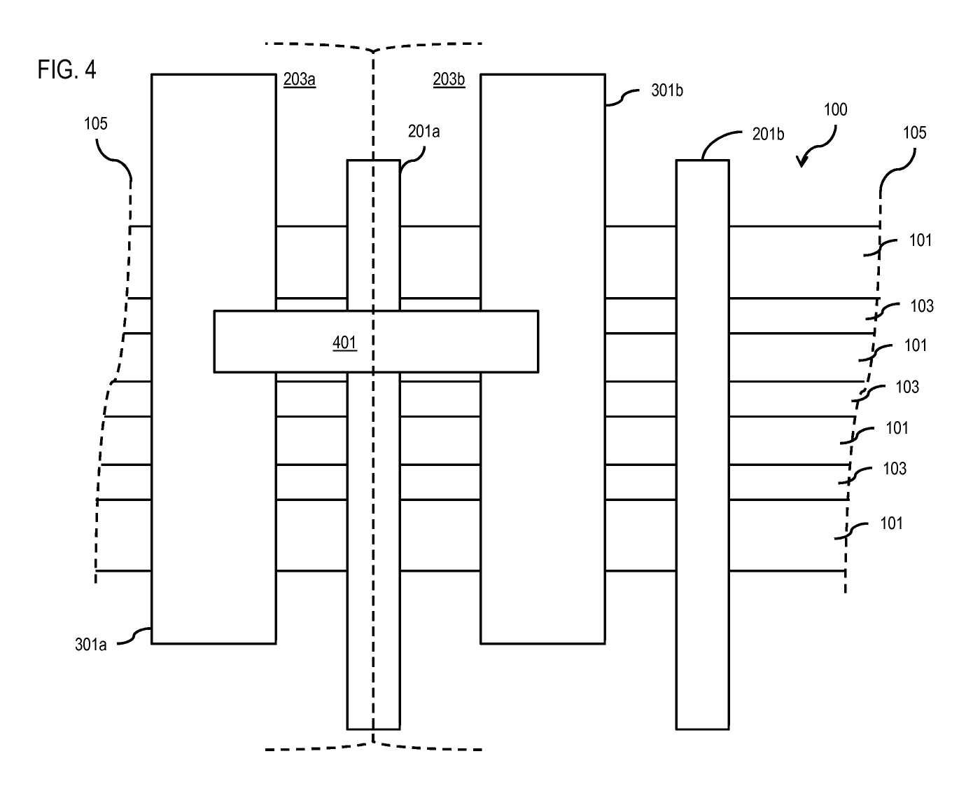

So that cells 203a and 203b can share gate 201a as a dummy gate, gate tie 401 is formed that acts as a short between source contact lines 301a and 301b, and gate 201a, as illustrated in FIG. 4.

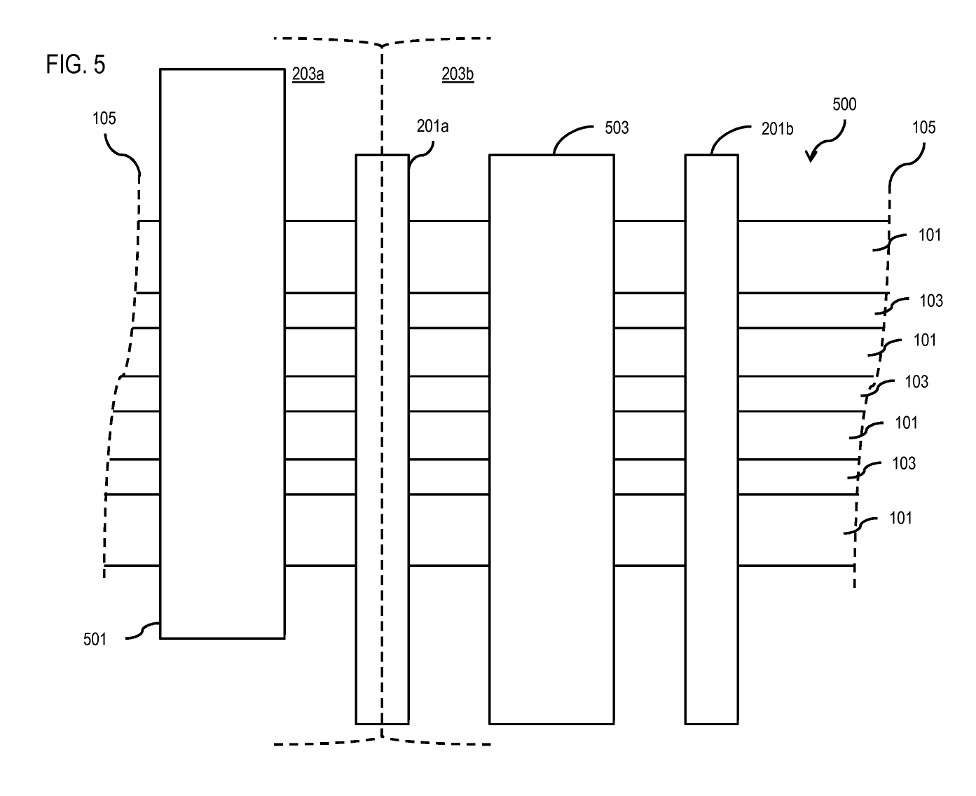

Adverting to FIG. 5, a method for forming abutting cells sharing a common dummy gate for source-to-drain (or drain-to-source) abutment, according to an exemplary embodiment, begins with a structure 500, which can include the same active region 101, fins 103, and gates 201a and 201b as illustrated in FIG. 4 for structure 100. However, rather than including two source contact lines 301a and 301b, structure 500 includes source contact line 501 and drain contact line 503, which are formed perpendicular to and over fins 103 on either side of gate 201a. The source contact line 501 and drain contact line 503 may be formed according to any conventional process. Although only one source contact line and one drain contact line are shown, more source and/or drain contact lines may be formed when forming source contact line 501 and drain contact line 503 (not shown for illustrative convenience). Further, although illustrated and described as source contact line 501 for cell 203a and drain contact line 503 for cell 203b, alternatively, cell 203a may include the drain contact line 503 and cell 203b may include the source contact line 501.

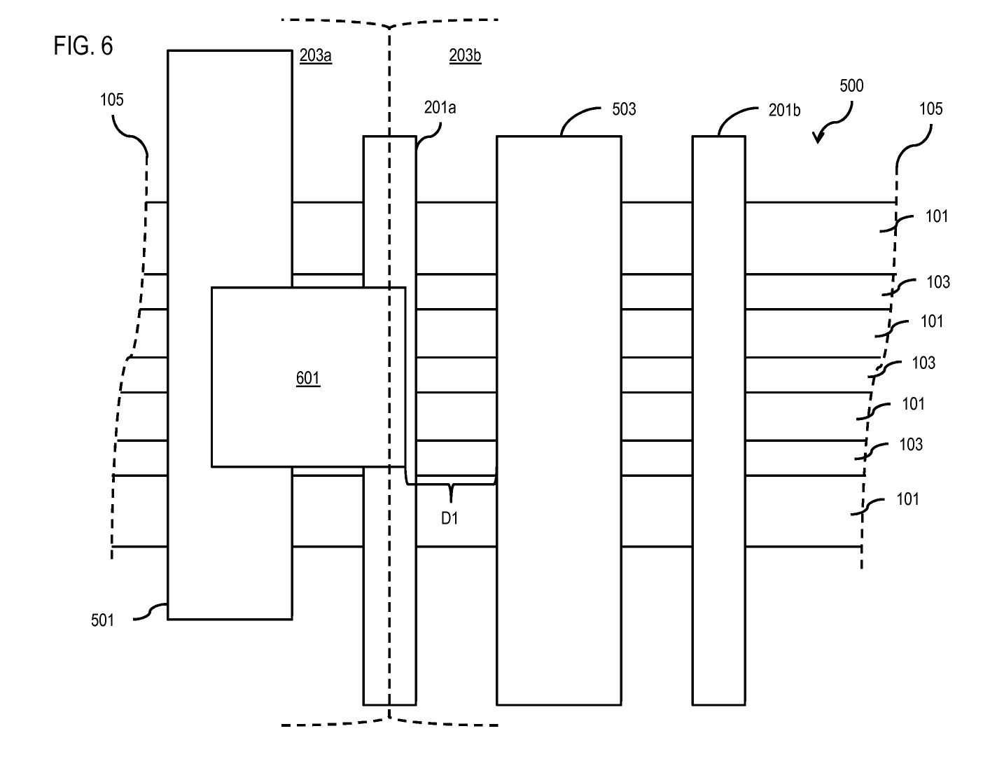

To tie off the gate 201a for cell 203a, a gate tie 601 is formed connecting the source contact line 501 to the gate 201a, as illustrated in FIG. 6. The gate tie 601 allows the cells 203a and 203b to abut without having a Fin-tuck and, therefore, allowing for a continuous active region 101 and continuous fins 103.

Formation of the source/drain contact lines 301a and 301a, or 501 and 503 discussed above may be associated with a contact layer (e.g., CA). Further, formation of the gate tie 401 or gate tie 601 may be associated with a contact layer (e.g., CB). Although discussed as different features or elements, the contact layer CA may be the same layer as the contact layer CB, such that the contact layers CA and CB are co-planar and formed of the same material. Thus, in forming the source/drain contact lines 301a and 301a, or 501 and 503, the gate tie 401, or gate tie 601, may also be formed.

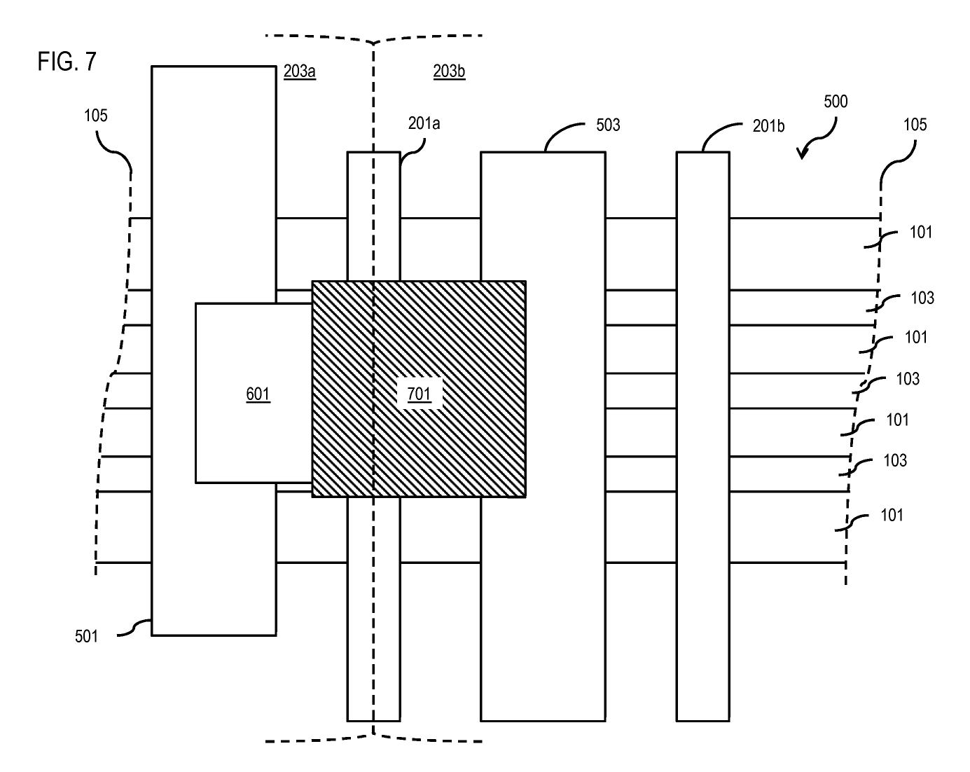

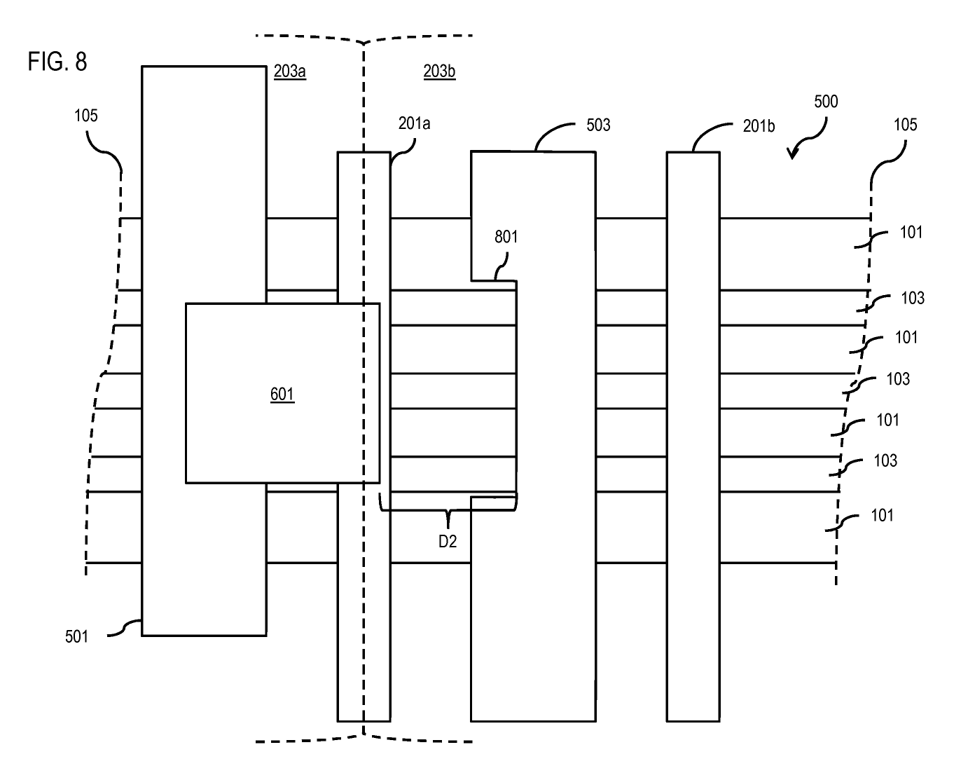

After forming the gate tie 601, a distance D1 between the gate tie 601 and the drain contact line 503 may violate design rules for the manufacturability of the structure 500. Adverting to FIG. 7, a cut mask 701 is used to remove a portion of the drain contact line 503 to increase the distance between the gate tie 601 and the drain contact line 503. The cut mask 701 may occur prior to forming the gate tie 601 or may occur in such a way that preserves or does not remove the gate tie 601 if the gate tie 601 is already present. After the cut mask 701, a notch 801 is formed in the drain contact line 503. The notch 801 modifies the drain contact line 503 to be a distance D2 from the left edge of the gate tie 601, where D2 is greater than D1, as illustrated in FIG. 8. At a distance D2, the gate tie 601 and drain contact line 503 no longer violate design rules because of their proximity.

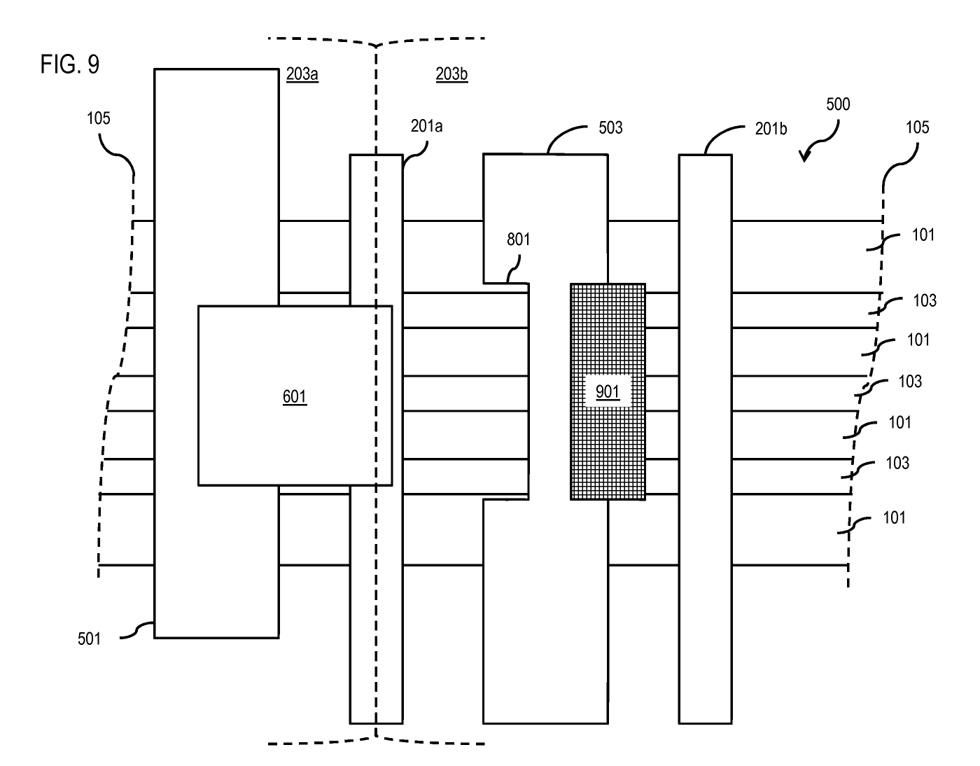

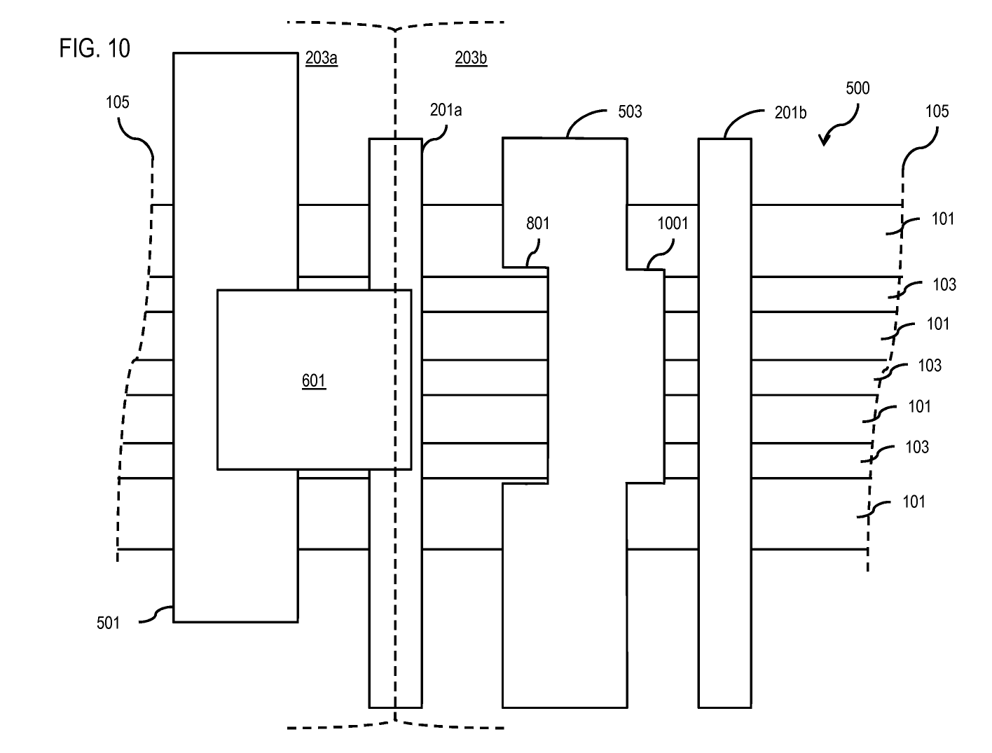

To prevent changing the characteristics of the drain contact line 503 caused by the change in thickness at the notch, a corresponding projection may be added to the right side of the drain contact line 503. FIG. 9 illustrates an optical proximity correction 901 used to form the projection. FIG. 10 illustrates the corresponding projection 1001 added to the drain contact line 503. The combination of the notch 801 and the projection 1001 forms a jog in the drain contact line 503 corresponding with the gate tie 601 to avoid violating any design rules or affecting performance of the drain contact line 503.

The embodiments of the present disclosure achieve several technical effects, including gate tie structures that can help reduce logic area by 3% to 5%. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras, particularly for 14 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming one or more continuous fins on a substrate;
forming gates perpendicular to and over the one or more continuous fins to form a first FinFET cell and a second FinFET cell; and
forming source and drain contact lines parallel to and between the gates, wherein a source contact line of the first FinFET cell is adjacent to a drain contact line of the second FinFET cell, and the source contact line and the drain contact line are on opposite sides of a gate.

2. The method according to claim 1, further comprising:
forming a gate tie extending a section of the source contact line to the gate.

3. The method according to claim 2, further comprising:
forming a jog in the drain contact line at a section of the drain contact line adjacent to the gate tie.

4. The method according to claim 3, wherein forming the jog comprises:
forming a notch in a side of the drain contact line nearest to the gate tie.

5. The method according to claim 4, comprising:
forming the notch using a cut mask on the drain contact line.

6. The method according to claim 3, wherein forming the jog further comprises:
forming a projection on a side of the drain contact line farthest from the gate tie.

7. The method according to claim 1, wherein the gate is a dummy gate.

8. An apparatus comprising:
a substrate;
one or more continuous fins on the substrate;
gates perpendicular to and over the one or more continuous fins, forming a first FinFET cell and a second FinFET cell; and
source and drain contact lines parallel to and between the gates, wherein a source contact line of the first FinFET cell is adjacent to a drain contact line of the second FinFET cell, and the source contact line and the drain contact line are on opposite sides of a gate.

9. The apparatus according to claim 8, further comprising:
a gate tie extending a section of the source contact line to the gate.

10. The apparatus according to claim 9, further comprising:
a jog in the drain contact line at a section of the drain contact line adjacent to the gate tie.

11. The apparatus according to claim 10, wherein the jog comprises:
a notch in a side of the drain contact line nearest to the gate tie.

12. The apparatus according to claim 11, wherein the notch is formed using a cut mask on the drain contact line.

13. The apparatus according to claim 10, wherein the jog further comprises:
a projection on a side of the drain contact line farthest from the gate tie.

14. The apparatus according to claim 8, wherein the gate is a dummy gate.

15. A method comprising:
forming one or more continuous fins on a substrate;
forming gates perpendicular to and over the one or more continuous fins to form a first FinFET cell and a second FinFET cell; and
forming source and drain contact lines parallel to and between the gates, wherein a source contact line of the first FinFET cell is adjacent to a source contact line of the second FinFET cell on opposite sides of a gate.

16. The method according to claim 15, further comprising:
forming a short connecting the source contact line of the first FinFET cell to the source contact line of the second FinFET cell.

17. The method according to claim 16, comprising:
forming the short connected to the gate,
wherein the gate is a dummy gate.

18. An apparatus comprising:
a substrate;
one or more continuous fins on the substrate;
gates perpendicular to and over the one or more continuous fins, forming a first FinFET cell and a second FinFET cell; and
source and drain contact lines parallel to and between the gates, wherein a source contact line of the first FinFET cell is adjacent to a source contact line of the second FinFET cell on opposite sides of a gate.

19. The apparatus according to claim 18, further comprising:
a short connecting the source contact line of the first FinFET cell to the source contact line of the second FinFET cell.

20. The apparatus according to claim 19, wherein the short is connected to the gate, and the gate is a dummy gate.
